(19) United States
(12) Patent Application Publication
(10) Pub. No.: US 2024/0387723 A1
(43) Pub. Date: Nov. 21, 2024

(54) SILICON CARBIDE SEMICONDUCTOR DEVICE AND METHOD FOR MANUFACTURING THE SAME

(71) Applicant: FUJI ELECTRIC CO., LTD., Kawasaki-shi (JP)

(72) Inventors: Tetsuya TAKAHASHI, Matsumoto-city (JP); Naoyuki OHSE, Matsumoto-city (JP)

(73) Assignee: FUJI ELECTRIC CO., LTD., Kawasaki-shi (JP)

(21) Appl. No.: 18/587,373

(22) Filed: Feb. 26, 2024

(30) Foreign Application Priority Data
May 15, 2023 (JP) 2023-080022

(51) Int. Cl. H01L 29/78; H01L 29/06; H01L 29/08; H01L 29/10; H01L 29/16; H01L 29/66

(52) U.S. Cl. CPC H01L 29/7813; H01L 29/0615; H01L 29/0856; H01L 29/1095; H01L 29/1608; H01L 29/66068

(57) ABSTRACT

Provided is a SiC semiconductor device that suppresses the decrease in the device design flexibility. The SiC semiconductor device includes a first SiC layer 14 containing SiC with a 4H structure, a second SiC layer 15 containing SiC with a 3C structure and stacked on the top face of the first SiC layer, a first conductivity type drift layer 2 provided in the first SiC layer, second conductivity type base regions 5a, 5b provided in the first SiC layer, first conductivity type main regions 6a, 6b including source extension regions 61a, 61b provided in the first SiC layer and source contact regions 62a, 62b provided in the second SiC layer, a gate insulating film 7b provided in a trench 7a penetrating the main region and the base region, a gate electrode 7c embedded in the trench, and a main electrode (11, 12) provided in contact with the source contact region.

### CROSS-REFERENCE TO RELATED APPLICATION

This application claims benefit of priority under 35 USC 119 based on Japanese Patent Application No. 2023-080022 filed on May 15, 2023, the entire contents of which are incorporated by reference herein.

### BACKGROUND OF THE INVENTION

### 1. Field of the Invention

The present disclosure relates to a sic semiconductor device including silicon carbide (SiC) and a method for manufacturing the device.

### 2. Description of the Related Art

JP 2009-49198 A discloses a semiconductor device that is manufactured by implanting phosphorus ions into a substrate of hexagonal single crystal silicon carbide to form an amorphous layer, recrystallizing the amorphous layer by heat treatment into cubic single crystals of n type silicon carbide, and depositing nickel on the top surface of the n type silicon carbide to form an electrode.

WO 2017/042963 A1 discloses a semiconductor device that has, in an n⁻ type epitaxial growth layer formed on a first main surface of an n⁺ type SiC substrate formed of 4H—SiC, an n⁺ type source region and has an n⁺ type 3C—SiC region and a p⁺ type potential fixing region that are formed in the n⁺ type source region. In the semiconductor device, a barrier metal film is formed in contact with the n⁺ type 3C—SiC region and the p⁺ type potential fixing region, and a source wiring electrode is formed on the barrier metal film.

If the boundary between a 3C—SiC region and a 4H—SiC region is unclear, the device design flexibility may decrease.

### SUMMARY OF INVENTION

Under such circumstances, the present disclosure is intended to provide a SiC semiconductor device that suppresses the decrease in the device design flexibility and a method for manufacturing the device.

An aspect of the disclosure is a SiC semiconductor device including a first silicon carbide layer containing silicon carbide with a 4H structure, a second silicon carbide layer containing silicon carbide with a 3C structure and stacked on the top face of the first silicon carbide layer, a first conductivity type drift layer provided in the first silicon carbide layer, a second conductivity type base region provided in the first silicon carbide layer on the top face side of the drift layer, a first conductivity type main region including a source extension region provided in the first silicon carbide layer and having a bottom face in contact with the base region and including a source contact region provided in the second silicon carbide layer and having a bottom face in contact with the source extension region, a gate insulating film provided in a trench penetrating the main region and the base region, a gate electrode embedded on the gate insulating film in the trench, and a main electrode provided in contact with the source contact region.

Another aspect of the disclosure is a method for manufacturing a SiC semiconductor device. The method includes forming a first silicon carbide layer containing silicon carbide with a 4H structure and including a first conductivity type drift layer, stacking a second silicon carbide layer containing silicon carbide with a 3C structure on the top face of the first silicon carbide layer, forming a second conductivity type base region in the first silicon carbide layer on the top face side of the drift layer, forming a first conductivity type main region having a multilayer structure of a source extension region and a source contact region over the first silicon carbide layer and the second silicon carbide layer, forming a trench penetrating the main region and the base region located on the bottom face side of the main region, forming a gate electrode on a gate insulating film in the trench, and forming a main electrode to be in contact with the top face of the source contact region. In the forming a main region, the source extension region is formed in the first silicon carbide layer, and the source contact region is formed in the second silicon carbide layer.

### BRIEF DESCRIPTION OF DRAWINGS

FIG. 1 is a plan view schematically illustrating an example of a SiC semiconductor device pertaining to a first embodiment;

FIG. 2 is a longitudinal sectional view illustrating a cross-sectional structure taken along line A-A in FIG. 1;

FIG. 3 is a schematic sectional view illustrating an enlarged region B in FIG. 2;

FIG. 4 is a schematic sectional view illustrating a SiC semiconductor device pertaining a comparative example;

FIG. 5 is a schematic sectional view illustrating an example method for manufacturing a SiC semiconductor device pertaining to a first embodiment;

FIG. 6 is a schematic sectional view illustrating an example method for manufacturing a SiC semiconductor device pertaining to the first embodiment, following FIG. 5;

FIG. 7 is a schematic sectional view illustrating an example method for manufacturing a SiC semiconductor device pertaining to the first embodiment, following FIG. 6;

FIG. 8 is a schematic sectional view illustrating an example method for manufacturing a SiC semiconductor device pertaining to the first embodiment, following FIG. 7;

FIG. 9 is a schematic sectional view illustrating an example method for manufacturing a SiC semiconductor device pertaining to the first embodiment, following FIG. 8;

FIG. 10 is a schematic sectional view illustrating an example method for manufacturing a SiC semiconductor device pertaining to the first embodiment, following FIG. 9;

FIG. 11 is a schematic sectional view illustrating an example method for manufacturing a SiC semiconductor device pertaining to the first embodiment, following FIG. 10;

FIG. 12 is a schematic sectional view illustrating an example method for manufacturing a SiC semiconductor device pertaining to the first embodiment, following FIG. 11;

FIG. 13 is a schematic sectional view illustrating an example method for manufacturing a SiC semiconductor device pertaining to the first embodiment, following FIG. 12; and

FIG. 14 is a schematic sectional view illustrating an example method for manufacturing a SiC semiconductor device pertaining to the first embodiment, following FIG. 13.

### DETAILED DESCRIPTION

A first embodiment of the present disclosure will now be described with reference to drawings. In the description of drawings, identical or similar components are indicated by an identical or similar sign and are not described. However, the drawings are schematic, and the relationship between thickness and plan dimension, the ratio of thicknesses of layers, or the like may differ from the actual ones. The dimensional relationships or ratios may differ between drawings. The first embodiment described below is merely illustrative examples of devices or methods for embodying the technical ideas of the present disclosure, and the technical ideas of the disclosure do not specify the materials, shapes, structures, arrangements, or the like of components as follows.

In the present description, the source region of a metal-oxide semiconductor field-effect transistor (MOSFET) is “one main region (first main region)” selectable as the emitter region of an insulated gate bipolar transistor (IGBT). In a thyristor such as a MOS-controlled static induction thyristor (SI thyristor), “one main region” is selectable as the cathode region. The drain region of a MOSFET is “the other main region (second main region)” of a semiconductor device that is selectable as the collector region in an IGBT and is selectable as the anode region in a thyristor. In the present description, a region simply called a “main region” means a first main region or a second main region reasonable on the basis of the general knowledge of a person skilled in the art.

In the following description, the definitions of directions such as up and down directions are merely for convenience of explanation and do not limit the technical ideas of the disclosure. For example, when an object is rotated by 90° and observed, the up and down directions are converted to left and right directions, and when an object is rotated by 180° and observed, the up and down directions are inverted, needless to say. A “top face” may also be read as a “front face”, and the “bottom face” may also be read as a “back face”.

In the following description, a case in which a first conductivity type is an n type and a second conductivity type is a p type will be described as an example. However, the relationship of the conductivity types may be inverted to set the first conductivity type to the p type and the second conductivity type to the n type. A semiconductor region denoted by n or p with + or − means that such a semiconductor region has a higher or lower impurity concentration than a semiconductor region denoted by n or p without + or −. It should be noted that a semiconductor region denoted by n and a semiconductor region denoted by the same n may not have exactly the same impurity concentration.

SiC crystals have polymorphism, and the main polymorphisms are cubic 3C and hexagonal 4H and 6H. It has been reported that at room temperature, 3C—SiC has a bandgap of 2.23 eV, 4H—SiC has a bandgap of 3.26 eV, and 6H—SiC has a bandgap of 3.02 eV. In the following description, a case in which 4H—SiC and 3C—SiC are mainly used will be illustrated.

### First Embodiment

### <Structure of SiC Semiconductor Device>

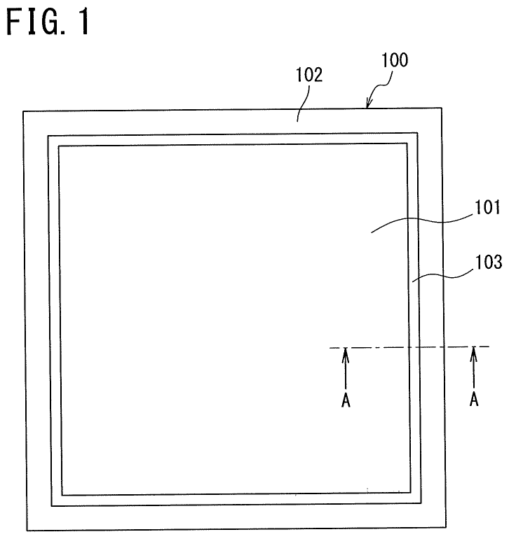

A SiC semiconductor device (silicon carbide semiconductor device, semiconductor chip) 100 pertaining to a first embodiment includes, as illustrated in FIG. 1, an active part 101, for example, having a rectangular planar shape and a breakdown voltage structure part 102 surrounding the periphery of the active part 101, in plan view. The SiC semiconductor device 100 also includes, between the active part 101 and the breakdown voltage structure part 102, a region 103 surrounding the active part 101, in plan view.

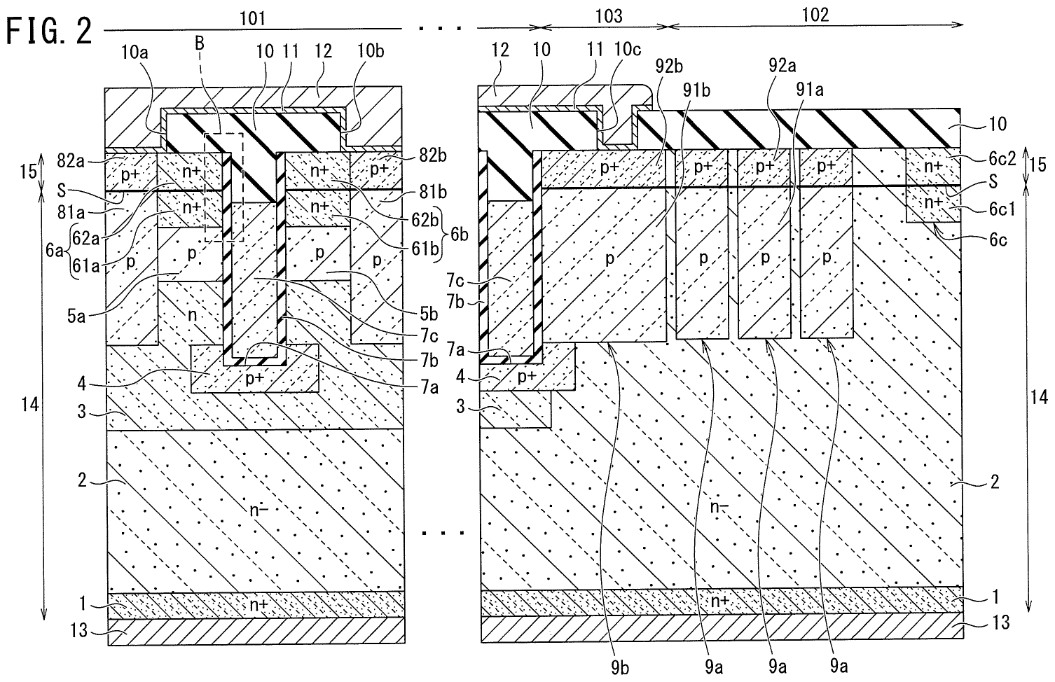

FIG. 2 is a sectional view taken along line A-A in FIG. 1. In FIG. 2, a part of the active part 101 is not illustrated. As illustrated in FIG. 2, the active part 101 includes an active element, the region 103 includes a ring region 9b, and the breakdown voltage structure part 102 includes, as the termination structure, a plurality of field relaxation regions 9a described later, as an example.

As illustrated in FIG. 2, the SiC semiconductor device 100 includes a trench-gate type MOSFET as the active element, as an example. FIG. 2 illustrates a unit cell including an insulated gate electrode structure (7b, 7c) embedded in one trench 7a, but in an actual device, a large number of these unit cells are arranged periodically.

The SiC semiconductor device 100 has a first silicon carbide layer 14 formed of silicon carbide and a second silicon carbide layer 15 formed of silicon carbide. The first silicon carbide layer 14 mainly contains 4H—SiC. The first silicon carbide layer 14 contains the 4H—SiC at a proportion of, for example, about 70 percent or more and 100 percent or less. The second silicon carbide layer 15 is a silicon carbide film stacked on the top face of the first silicon carbide layer 14 and contains 3C—SiC. The second silicon carbide layer 15 contains the 3C—SiC at a proportion of, for example, about 10 percent or more and 100 percent or less. Hereinafter, 3C—SiC may also be called a 3C structure, and 4H—SiC may also be called a 4H structure. The second silicon carbide layer 15 has an almost uniform film thickness in the chip plane of the SiC semiconductor device 100.

The first silicon carbide layer 14 is provided over the active part 101, the breakdown voltage structure part 102, and the region 103. The second silicon carbide layer 15 is stacked on the top face of the first silicon carbide layer 14 over the active part 101, the breakdown voltage structure part 102, and the region 103. The boundary face between the first silicon carbide layer 14 and the second silicon carbide layer 15 is called a boundary face S. More specifically, the boundary face between the top face of the first silicon carbide layer 14 and the bottom face of the second silicon carbide layer 15 is called a boundary face S. The boundary face S can be identified when a longitudinal section of the SiC semiconductor device 100 is observed. As illustrated in FIG. 2, when observed in a sectional view, the boundary face S looks linear depending on the surface condition of the top face of the first silicon carbide layer 14, for example. The second silicon carbide layer 15 contains 3C—SiC at least in the top face portion (the portion opposite to the first silicon carbide layer 14).

The SiC semiconductor device 100 includes a first conductivity type (n⁻ type) drift layer 2 provided over the active part 101, the breakdown voltage structure part 102, and the region 103. The drift layer 2 is provided in the first silicon carbide layer 14. The drift layer 2 includes, for example, an epitaxial growth layer formed of SiC such as 4H—SiC. The drift layer 2 has an impurity concentration of, for example, about 1×10¹⁵ cm⁻³ or more and 5×10¹⁶ cm⁻³ or less. The drift layer 2 has a thickness of, for example, about 1 μm or more and 100 μm or less. The impurity concentration and the thickness of the drift layer 2 can be appropriately adjusted according to withstand voltage specifications or the like.

Over the active part 101 and the region 103, a first conductivity type (n type) current spreading layer (CSL) 3 having a higher impurity concentration than the drift layer 2 is selectively provided on the top face side of the drift layer 2. The current spreading layer 3 is provided in the first silicon carbide layer 14. The bottom face of the current spreading layer 3 is in contact with the top face of the drift layer 2. The current spreading layer 3 is formed, for example, by ion implantation of N. The current spreading layer 3 has an impurity concentration of, for example, about 5×10¹⁶ cm⁻³ or more and 5×10¹⁷ cm⁻³ or less. The current spreading layer 3 is not necessarily provided. When no current spreading layer 3 is provided, the drift layer 2 may be provided to the region of the current spreading layer 3.

In the active part 101, second conductivity type (p type) base regions 5a, 5b are selectively provided on the top face side of the current spreading layer 3. The base regions 5a, 5b are provided in the first silicon carbide layer 14. The bottom faces of the base regions 5a, 5b are in contact with the top face of the current spreading layer 3. When no current spreading layer 3 is provided, the bottom faces of the base regions 5a, 5b are in contact with the top face of the drift layer 2. The base regions 5a, 5b are, for example, regions of a SiC formed by subjecting the current spreading layer 3 to ion implantation of p type impurities such as aluminum. The base regions 5a, 5b may include an epitaxial growth layer formed of SiC such as 4H—SiC. The base regions 5a, 5b have an impurity concentration of, for example, about 1×10¹⁶ cm⁻³ or more and 1×10¹⁸ cm⁻³ or less.

On the top face sides of the base regions 5a, 5b in the active part 101, first conductivity type (n⁺ type) first main regions (source regions) 6a, 6b having a higher impurity concentration than the drift layer 2 are selectively provided. The source regions 6a, 6b are provided over the first silicon carbide layer 14 and the second silicon carbide layer 15. The source regions 6a, 6b are, for example, regions of a SiC formed by subjecting regions over the second silicon carbide layer 15 and the current spreading layer 3 to ion implantation of n type impurities. The n type impurities, for example, include phosphorus (P) or nitrogen (N). The source regions 6a, 6b may contain arsenic (As) as the n type impurities. The source regions 6a, 6b have an impurity concentration of, for example, about not less than 2×10¹⁹ cm⁻³ and less than 1×10²⁰ cm⁻³.

The source region 6a has a multilayer structure of two layers including an n⁺ type source extension region 61a as the lower layer and an n⁺ type source contact region 62a as the upper layer. The bottom face of the source extension region 61a is in contact with the top face of the base region 5a. The top face of the source extension region 61a is in contact with the bottom face of the source contact region 62a. The source region 6b has a multilayer structure of two layers including an n⁺ type source extension region 61b as the lower layer and an n⁺ type source contact region 62b as the upper layer. The bottom face of the source extension region 61b is in contact with the top face of the base region 5b. The top face of the source extension region 61b is in contact with the bottom face of the source contact region 62b.

The source extension regions 61a, 61b of the source regions 6a, 6b are provided in the first silicon carbide layer 14, and the source contact regions 62a, 62b are provided in the second silicon carbide layer 15. In other words, portions of the source regions 6a, 6b provided in the first silicon carbide layer 14 are called source extension regions 61a, 61b and portions provided in the second silicon carbide layer 15 are called source contact regions 62a, 62b. The source extension region 61a and the source contact region 62a are divided by the boundary face S, and the source extension region 61b and the source contact region 62b are also divided by the boundary face S. The source extension regions 61a, 61b include no second silicon carbide layer 15. Hence, the source extension regions 61a, 61b contain no mixed crystals of 3C—SiC and 4H—SiC or contains few mixed crystals of 3C—SiC and 4H—SiC, if any.

The source contact regions 62a, 62b contain 3C—SiC. The source contact regions 62a, 62b contain 3C—SiC at the same proportion as the second silicon carbide layer 15, and the proportion is, for example, about 10 percent or more and 100 percent or less. When the proportion of 3C—SiC is 100 percent, the source contact regions 62a, 62b and the second silicon carbide layer 15 are formed of 3C—SiC. When the proportion of 3C—SiC is less than 100 percent, the source contact regions 62a, 62b and the second silicon carbide layer 15 may contain mixed crystals of 3C—SiC and 4H—SiC. The source contact regions 62a, 62b are formed from the top face to the bottom face of the second silicon carbide layer 15. Hence, the source contact regions 62a, 62b have the same dimension along the depth direction as the second silicon carbide layer 15.

As illustrated in FIG. 2, a trench 7a penetrating the source regions 6a, 6b and the base regions 5a, 5b is provided from the top faces of the source regions 6a, 6b in the normal direction of the top faces of the source regions 6a, 6b (in the depth direction). The bottom face of the trench 7a reaches the current spreading layer 3. The trench 7a has a width of, for example, about 1 μm or less. The left face of the trench 7a is in contact with the source region 6a and the base region 5a. The right face of the trench 7a is in contact with the source region 6b and the base region 5b. The trench 7a may have a plane pattern of a stripe extending in the back direction and the front direction of the plane of FIG. 2 or may have a plane pattern of dots.

On the bottom face and both side faces of the trench 7a, a gate insulating film 7b is provided. In the trench 7a, a gate electrode 7c is embedded on the gate insulating film 7b. The gate insulating film 7b and the gate electrode 7c constitute a trench-gate type insulated gate electrode structure (7b, 7c).

As the gate insulating film 7b, a single layer film of one of a silicone oxide film (SiO₂ film), a silicon oxynitride (SiON) film, a strontium oxide (SrO) film, a silicon nitride (Si₃N₄) film, an aluminum oxide (Al₂O₃) film, a magnesium oxide (MgO) film, a yttrium oxide (Y₂O₃) film, a hafnium oxide (HfO₂) film, a zirconium oxide (ZrO₂) film, a tantalum oxide (Ta₂O₅) film, and a bismuth oxide (Bi₂O₃) film, a composite film prepared by stacking a plurality of such films, or the like is usable. As the material of the gate electrode 7c, for example, a polysilicon layer containing p type impurities or n type impurities at a high impurity concentration (doped polysilicon layer) or a high-melting point metal such as titanium (Ti), tungsten (W), or nickel (Ni) is usable.

In the current spreading layer 3 and on the bottom part of the trench 7a, a second conductivity type (p⁺ type) gate bottom protection region 4 is provided. The gate bottom protection region 4 is provided in the first silicon carbide layer 14. The top face of the gate bottom protection region 4 is in contact with the bottom face of the trench 7a. The top face of the gate bottom protection region 4 may not be in contact with the bottom face of the trench 7a. The gate bottom protection region 4 has an impurity concentration of, for example, about 1×10¹⁷ cm⁻³ or more and 1×10¹⁹ cm⁻³ or less. The gate bottom protection region 4 is, for example, a region of a SiC formed by subjecting the current spreading layer 3 to ion implantation of p type impurities. The gate bottom protection region 4 is electrically connected to a source wiring electrode 12 in a portion not illustrated in drawings. When the MOSFET is in the off state, the region is depleted and functions to relax the electric field applied to the bottom face of the trench 7a.

On the top face side of the current spreading layer 3, second conductivity type (p type) buried regions 81a, 81b are selectively provided to be in contact with the base regions 5a, 5b. The buried regions 81a, 81b are provided in the first silicon carbide layer 14. The bottom faces of the buried regions 81a, 81b are in contact with the current spreading layer 3. The side face of the buried region 81a is in contact with the current spreading layer 3 and the base region 5a, and the side face of the buried region 81b is in contact with the current spreading layer 3 and the base region 5b. The buried regions 81a, 81b are, for example, regions of a SiC formed by subjecting the current spreading layer 3 to ion implantation of p type impurities. The buried regions 81a, 81b have an impurity concentration of, for example, about 5×10¹⁷ cm⁻³ or more and 1×10¹⁹ cm⁻³ or less.

On the top face sides of the buried regions 81a, 81b, p⁺ type base contact regions 82a, 82b having a higher impurity concentration than the buried region 81a are selectively provided. The base contact regions 82a, 82b are provided in the second silicon carbide layer 15. The bottom face of the base contact region 82a is in contact with the top face of the buried region 81a, and the side face of the base contact region 82a is in contact with the source region 6a. The bottom face of the base contact region 82b is in contact with the top face of the buried region 81b, and the side face of the base contact region 82b is in contact with the source region 6b. The base contact region 82a is electrically connected to the base region 5a, and the base contact region 82b is electrically connected to the base region 5b. The base contact regions 82a, 82b are, for example, regions of a SiC formed by subjecting the second silicon carbide layer 15 to ion implantation of p type impurities. The base contact regions 82a, 82b have an impurity concentration of, for example, about not less than 2×10¹⁹ cm⁻³ and less than 1×10²⁰ cm⁻³.

The buried regions 81a, 81b and the base contact regions 82a, 82b are regions of a p type SiC formed by ion implanting p type impurities over the second silicon carbide layer 15 and the first silicon carbide layer 14. Of the regions of a p type SiC, portions provided in the first silicon carbide layer 14 are called buried regions 81a, 81b, and portions provided in the second silicon carbide layer 15 are called base contact regions 82a, 82b. The buried region 81a and the base contact region 82a are divided by the boundary face S, and the buried region 81b and the base contact region 82b are also divided by the boundary face S. The buried regions 81a, 81b include no second silicon carbide layer 15. Hence, the buried regions 81a, 81b contain no mixed crystals of 3C—SiC and 4H—SiC or contains few mixed crystals of 3C—SiC and 4H—SiC, if any.

The base contact regions 82a, 82b contain 3C—SiC. The proportion of 3C—SiC contained in the base contact regions 82a, 82b is the same as in the second silicon carbide layer 15 and is, for example, about 10 percent or more and 100 percent or less. When the proportion of 3C—SiC is 100 percent, the base contact regions 82a, 82b and the second silicon carbide layer 15 are formed of 3C—SiC. When the proportion of 3C—SiC is less than 100 percent, the base contact regions 82a, 82b and the second silicon carbide layer 15 may contain mixed crystals of 3C—SiC and 4H—SiC. The base contact regions 82a, 82b contain 3C—SiC, and this can suppress the contact resistance with a source electrode (11, 12) described later. The base contact regions 82a, 82b are formed from the top face to the bottom face of the second silicon carbide layer 15. Hence, the base contact regions 82a, 82b have the same dimension along the depth direction as the second silicon carbide layer 15 and the source contact regions 62a, 62b.

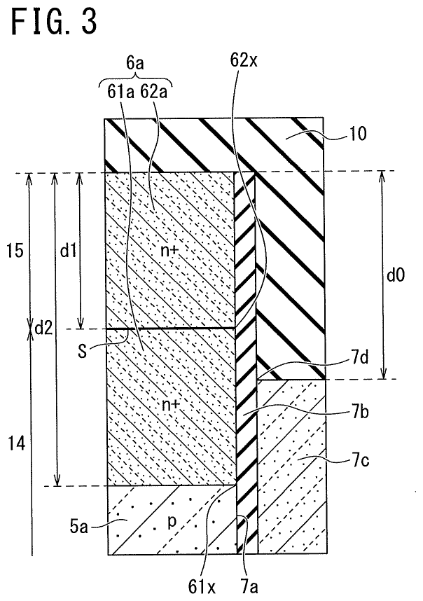

FIG. 3 is an enlarged view of region B in FIG. 2. With reference to FIG. 3, the configuration of the gate electrode 7c and the source region 6a will be described in further detail. The dimension along the depth direction of the source contact region 62a and the second silicon carbide layer 15 is denoted as d1. The dimension d1 is, for example, about 0.2 μm or more and 0.5 μm or less. The dimension along the depth direction of the source region 6a is denoted as d2. The dimension d2 is, for example, about 1 μm. The source contact region 62a contains 3C—SiC and thus can be in ohmic contact with the source electrode (11, 12) at a low resistance.

The top face (upper end) 7d at an end of the gate electrode 7c in contact with the gate insulating film 7b is located deeper than the bottom face (lower end) 62x of the source contact region 62a in contact with the gate insulating film 7b. In other words, the top face 7d of the gate electrode 7c in contact with the gate insulating film 7b is located deeper than the boundary face S. The top face (upper end) 7d at an end of the gate electrode 7c in contact with the gate insulating film 7b is located shallower than the bottom face of the source extension region 61a, more specifically than the bottom face (lower end) 61x of the source extension region 61a in contact with the gate insulating film 7b.

The top face 7d of the gate electrode 7c in contact with the gate insulating film 7b may be the uppermost face of the gate electrode 7c. For example, when the entire top face of a gate electrode 7c is a curved surface convex downward, the center of the top face of the gate electrode 7c may be located deeper than the edge of the top face 7d of the gate electrode 7c.

The gate electrode 7c faces the source extension region 61a through the gate insulating film 7b. More specifically, the gate electrode 7c faces the first silicon carbide layer 14 through the gate insulating film 7b. The gate electrode 7c does not face the source contact region 62a through the gate insulating film 7b. More specifically, the gate electrode 7c does not face the second silicon carbide layer 15 through the gate insulating film 7b. The source contact region 62a faces the insulating film 10 through the gate insulating film 7b. More specifically, the second silicon carbide layer 15 faces the insulating film 10 through the gate insulating film 7b. The amount of fall do of the gate electrode 7c from the top face of the source contact region 62a is larger than the dimension d1 along the depth direction of the source contact region 62a and the second silicon carbide layer 15 (d1<d0). The amount of fall do of the gate electrode 7c and the position of the top face 7d of the gate electrode 7c in contact with the gate insulating film 7b can be controlled, for example, by adjusting the etching conditions of the gate electrode 7c. The source extension region 61a contains no 3C—SiC or contains little if any, and thus has fewer crystal defects than the source contact region 62a.

The source extension region 61b and the source contact region 62b of the source region 6b illustrated in FIG. 2 have substantially the same configurations as the source extension region 61a and the source contact region 62a, respectively, of the source region 6a and the overlapping explanation will not be described. The positional relationship between the source extension region 61b and the source contact region 62b of the source region 6b and the gate electrode 7c is substantially the same as the positional relationship of the source extension region 61a and the source contact region 62a of the source region 6a and the gate electrode 7c, and the overlapping explanation will not be described.

As illustrated in FIG. 2, in the breakdown voltage structure part 102, a plurality of second conductivity type (p type) field relaxation regions 9a are selectively provided on the top face side of the drift layer 2. In an example illustrated in FIG. 2, three field relaxation regions 9a are provided on the top face side of the drift layer 2. The field relaxation regions 9a are concentric guard rings (field limiting rings) in plan view, not illustrated in the drawings. The field relaxation regions 9a are separated from each other by the drift layer 2. The bottom faces of the field relaxation regions 9a are in contact with the top face of the drift layer 2. Each field relaxation region 9a is, for example, a region of a SiC formed by subjecting the drift layer 2 and the second silicon carbide layer 15 to ion implantation of p type impurities such as aluminum.

The field relaxation region 9a is provided over the second silicon carbide layer 15 and the first silicon carbide layer 14 in the depth direction. Of the field relaxation region 9a, a portion provided in the first silicon carbide layer 14 is called a first portion 91a, and a portion provided in the second silicon carbide layer 15 is called a second portion 92a. The first portion 91a and the second portion 92a are divided by the boundary face S. The second portion 92a has the same dimension along the depth direction as the second silicon carbide layer 15. The first portion 91a is, for example, of a p type having substantially the same impurity concentration as the impurity concentration of the buried regions 81a, 81b. The second portion 92a is, for example, of a p⁺ type having substantially the same impurity concentration as that of the base contact regions 82a, 82b.

In the breakdown voltage structure part 102, a first conductivity type (n⁺ type) channel stopper region 6c is provided at the outermost periphery on the top face side of the drift layer 2. The channel stopper region 6c is provided so as to run along the outer periphery of the breakdown voltage structure part 102 in plan view, and has a bottom face in contact with the top face of the drift layer 2. Of the channel stopper region 6c, a portion provided in the first silicon carbide layer 14 is called a first portion 6c1, and a portion provided in the second silicon carbide layer 15 is called a second portion 6c2. The first portion 6c1 and the second portion 6c2 are divided by the boundary face S. The channel stopper region 6c is, for example, a region of a 3C—SiC formed by subjecting the drift layer 2 and the second silicon carbide layer 15 to ion implantation of n type impurities. The first portion 6c1 and the second portion 6c2 have substantially the same impurity concentration, for example, as the impurity concentration of the source regions 6a, 6b.

In the region 103, a second conductivity type (p type) ring region 9b is selectively provided on the top face side of the drift layer 2. The bottom face of the ring region 9b is in contact with the top face of the drift layer 2. The ring region 9b is, for example, a region of a SiC formed by subjecting the drift layer 2 to ion implantation of p type impurities. The ring region 9b is a ring-shaped portion surrounding the edge of the active part 101 in plan view, not illustrated in the drawings.

The ring region 9b is provided over the second silicon carbide layer 15 and the first silicon carbide layer 14 in the depth direction. Of the ring region 9b, a portion provided in the first silicon carbide layer 14 is called a first portion 91b, and a portion provided in the second silicon carbide layer 15 is called a second portion 92b. The first portion 91b and the second portion 92b are divided by the boundary face S. The second portion 92b has the same dimension along the depth direction as the second silicon carbide layer 15. The first portion 91b is, for example, of a p type having substantially the same impurity concentration as the impurity concentration of the buried regions 81a, 81b. The second portion 92b is, for example, of a p⁺ type having substantially the same impurity concentration as that of the base contact regions 82a, 82b.

On the top face side of the gate electrode 7c, the top face side of the region 103, and the top face side of the breakdown voltage structure part 102, an insulating film 10 is selectively provided. In the breakdown voltage structure part 102, the insulating film 10 is provided on the top faces of the field relaxation regions 9a. More specifically, the insulating film 10 is provided in positions to cover the second portions 92a of the field relaxation regions 9a. The insulating film 10 is constituted of a single layer film such as a silicone oxide film containing boron (B) and phosphorus (P) (BPSG film), a silicone oxide film containing phosphorus (P) (PSG film), a non-doped silicone oxide film called “NSG” and containing neither phosphorus (P) nor boron (B), a silicone oxide film containing boron (B) (BSG film), and a silicon nitride film (Si₃N₄ film), or a stacked-layer film thereof, for example. The insulating film 10 has contact holes 10a, 10b through which the top faces of the source regions 6a, 6b and the base contact regions 82a, 82b are exposed. The insulating film 10 also has a contact hole 10c through which the top face of the ring region 9b, more specifically the top face of the second portion 92b, is exposed.

A first main electrode (source electrode) (11, 12) is provided so as to cover the insulating film 10, the top faces of the source regions 6a, 6b and the base contact regions 82a, 82b exposed through the contact holes 10a, 10b, and the top face of the ring region 9b exposed through the contact hole 10c. The source electrode (11, 12) includes a lower barrier metal layer 11 and an upper source wiring electrode 12. For example, the barrier metal layer 11 includes a metal such as titanium nitride (TiN), titanium (Ti), or a TiN/Ti multilayer structure in which Ti is the lower layer. The barrier metal layer 11 is in direct contact with the top faces of the source contact regions 62a, 62b and the top faces of the base contact regions 82a, 82b and is in ohmic contact with the source contact regions 62a, 62b and the base contact regions 82a, 82b at a low resistance. The barrier metal layer 11 is also in direct contact with the second portion 92b of the ring region 9b and is in ohmic contact with the second portion 92b at a low resistance. The top faces of the second portions 92a of the field relaxation regions 9a are covered with the insulating film 10 and thus are not in contact with the barrier metal layer 11.

The source wiring electrode 12 is electrically connected through the barrier metal layer 11 to the source regions 6a, 6b, the base contact regions 82a, 82b, and the ring region 9b. The source wiring electrode 12 is provided separately from a gate wiring electrode (not illustrated) that is electrically connected to the gate electrode 7c. The source wiring electrode 12, for example, includes a metal such as aluminum (Al), aluminum-silicon (Al—Si), aluminum-copper (Al—Cu), and copper (Cu).

On the bottom face side of the drift layer 2, a first conductivity type (n⁺ type) second main region (drain region) 1 having a higher impurity concentration than the drift layer 2 is provided. The drain region 1, for example, includes a semiconductor substrate (SiC substrate) formed of 4H—SiC. The drain region 1 has an impurity concentration of, for example, about 1×10¹⁸ cm⁻³ or more and 3×10²⁰ cm⁻³ or less. The drain region 1 has a thickness of, for example, about 30 μm or more and 500 μm or less. Between the drift layer 2 and the drain region 1, a dislocation conversion layer or a recombination enhancement layer that is an n type buffer layer having a higher impurity concentration than the drift layer 2 and having a lower impurity concentration than the drain region 1 may be provided.

On the bottom face side of the drain region 1, a second main electrode (drain electrode) 13 is provided. As the drain electrode 13, for example, a single layer film of gold (Au) or a metal film in which titanium (Ti), nickel (Ni), and Au are stacked in this order from the drain region 1 is usable, and a metal film such as a molybdenum (Mo) film and a tungsten (W) film may be further stacked as the lowermost layer. Between the drain region 1 and the drain electrode 13, a drain contact layer such as a nickel silicide (NiSiₓ) film may be provided for ohmic contact.

The SiC semiconductor device according to the first embodiment during the operation applies a positive voltage to the drain electrode 13 while using the source electrode (11, 12) as a ground potential, and causes an inversion layer (a channel) to be formed in the respective base regions 5a and 5b toward the side surfaces of the trench 7a so as to be in the ON-state when a positive voltage of a threshold or greater is applied to the gate electrode 7c. In the ON-state, a current flows from the drain electrode 13 toward the source electrode (11, 12) through the drain region 1, the drift layer 2, the current spreading layer 3, the inversion layers of the base regions 5a and 5b, and the source regions 6a and 6b. When the voltage applied to the gate electrode 7c is smaller than the threshold, the SiC semiconductor device is led to be the OFF-state since no inversion channel is formed in the base region 5a, 5b, and no current flows from the drain electrode 13 toward the source electrode (11, 12).

In the SiC semiconductor device pertaining to the first embodiment, the source regions 6a, 6b has a two-layer structure of the source extension region 61a, 61b and the source contact region 62a, 62b, and the upper source contact region 62a, 62b in contact with the source electrode (11, 12) contains 3C—SiC. This enables ohmic contact between the source contact region 62a, 62b and the source electrode (11, 12) at a low resistance without forming a silicide layer such as a nickel (Ni) silicide layer. Accordingly, disadvantages such as silicide layer release can be suppressed as compared with when a silicide layer is formed.

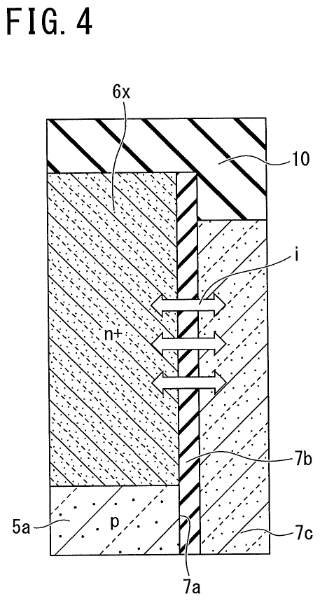

As illustrated in FIG. 4, a case in which a source region 6x containing 3C—SiC is formed as a single layer structure and the source region 6x faces a gate electrode 7c through a gate insulating film 7b is supposed. In this case, the source region 6x contains 3C—SiC, and thus the source region 6x can be in ohmic contact with the source electrode (11, 12). However, 3C—SiC has more crystal defects than 4H—SiC and gives large surface irregularities. Accordingly, leak current i may flow between the gate electrode 7c and the source region 6x.

In contrast, in the SiC semiconductor device 100 pertaining to the first embodiment, as illustrated in FIG. 3, the top face 7d of the gate electrode 7c in contact with the gate insulating film 7b is deeper than the boundary face S between the first silicon carbide layer 14 and the second silicon carbide layer 15 and is shallower than the bottom face 61x of the source extension region 61a. Accordingly, of the source region 6a, the source extension region 61a provided in the first silicon carbide layer 14 having fewer crystal defects faces the gate electrode 7c through the gate insulating film 7b, and of the source region 6a, the source contact region 62a provided in the second silicon carbide layer 15 having more crystal defects does not face the gate electrode 7c through the gate insulating film 7b. This can suppress leak current between the source region 6a and the gate electrode 7c.

In a conventional case, a hexagonal single crystal silicon carbide substrate is subjected to ion implantation of phosphorus to form an amorphous layer, and the amorphous layer is recrystallized by heat treatment into cubic single crystals of n type silicon carbide. However, ion implantation of impurities gives an unclear boundary between a high impurity concentration region and a low impurity concentration region in the SiC. Accordingly, the SiC after heat treatment may have an unclear boundary between a region containing 3C—SiC and a region containing almost no 3C—SiC. A planar type SiC semiconductor device has a gate electrode on the top face of SiC, whereas a trench type SiC semiconductor device has a gate electrode in a trench along the depth direction (thickness direction). Hence, a region containing 3C—SiC for suppressing contact resistance is required to be prepared separately from a region of 4H—SiC along the depth direction. In typical ion implantation of impurities, controlling the impurity concentration in the depth direction is more difficult than controlling the impurity concentration in the transverse direction. More specifically, the impurity concentration in the transverse direction can be controlled, for example, by using a mask pattern. In contrast, the impurity concentration in the depth direction is controlled by adjusting the impurity dose amount and the acceleration energy, and thus controlling the impurity concentration in the depth direction is more difficult than controlling the impurity concentration in the transverse direction. Accordingly, in a trench type SiC semiconductor device, the boundary between a region containing 3C—SiC and a region containing almost no 3C—SiC may not be easily specified. In some cases, a little more margin may be designed to suppress leak current i, and a little more amount of fall do of a gate electrode 7c from the top face of a source contact region 62a may be set. As described above, the device design flexibility may decrease.

In contrast, the SiC semiconductor device 100 pertaining to the first embodiment has a multilayer structure of the first silicon carbide layer containing silicon carbide with a 4H structure 14 and the second silicon carbide layer 15 stacked on the top face of the first silicon carbide layer 14 and formed of silicon carbide containing 3C—SiC. Accordingly, the boundary between a region containing 3C—SiC and a region mainly formed of silicon carbide with a 4H structure becomes clear as the boundary face S. It is thus obvious that a region deeper than the boundary face S contains no mixed crystals of 3C—SiC and 4H—SiC or contains few mixed crystals of 3C—SiC and 4H—SiC, if any. Hence, the top face 7d of the gate electrode 7c in contact with the gate insulating film 7b can be designed at a position deeper than the boundary face S. Accordingly, leak current i can be suppressed without setting a little more margin, and the decrease in the device design flexibility can be suppressed.

### <Method for Manufacturing SiC Semiconductor Device>

An example method for manufacturing the SiC semiconductor device pertaining to the first embodiment will next be described. The method for manufacturing a SiC semiconductor device described below is an example, and the manufacturing can be achieved by various other manufacturing methods including the alternative embodiment, within the scope described in claims, needless to say.

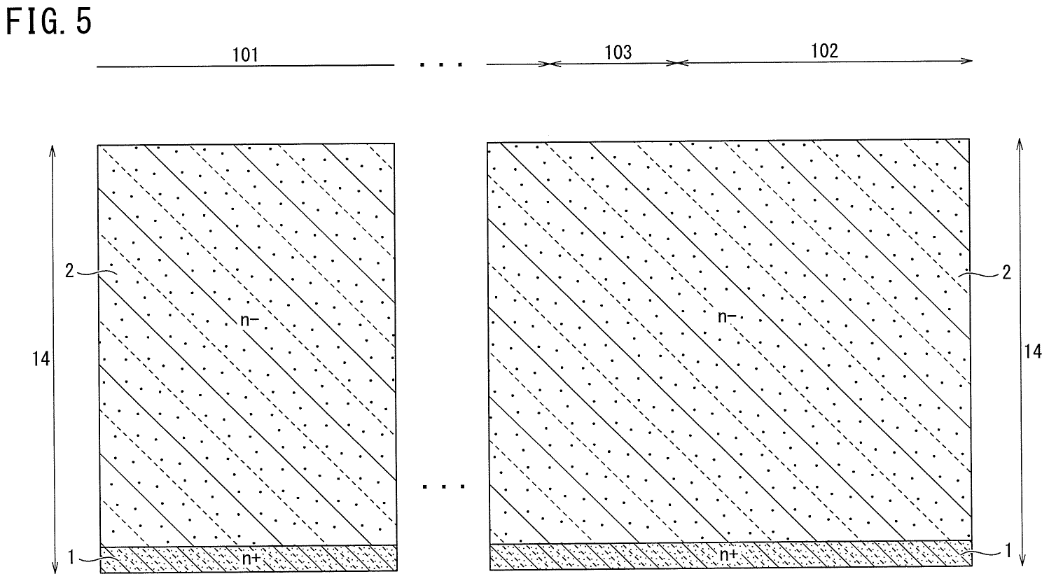

First, as illustrated in FIG. 5, a semiconductor substrate (SiC substrate) 1 of an n⁺ type 4H—SiC containing n type impurities such as nitrogen (N) is prepared. The top face of the SiC substrate 1, for example, has an off angle of 3 degrees to 8 degrees from {0001} plane. On the top face of the SiC substrate 1, a drift layer 2 of an n⁻ type 4H—SiC containing n type impurities such as N and having a lower impurity concentration than the SiC substrate 1 is epitaxially grown. A first silicon carbide layer 14 is accordingly prepared.

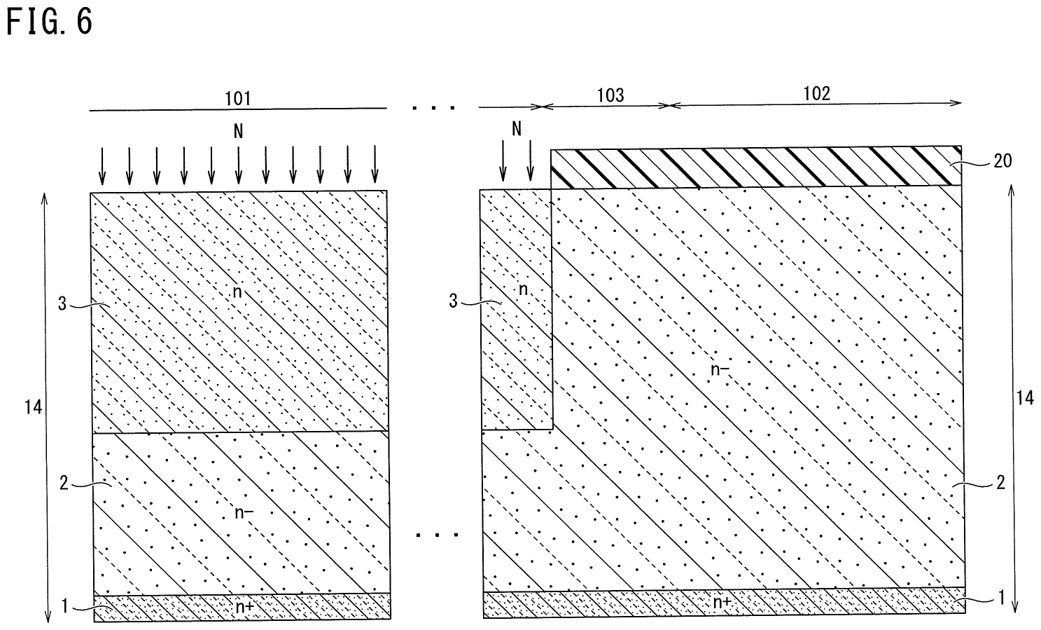

Next, as illustrated in FIG. 6, a mask pattern 20 of a photoresist film is formed on the top face of the drift layer 2 by a photolithographic technology. With the mask pattern 20 as an ion implantation mask, the upper part of the drift layer 2 is subjected to ion implantation of n type impurities such as nitrogen (N), and an n type current spreading layer 3 of 4H—SiC is formed. The mask pattern 20 is then removed. The mask pattern 20 may be, for example, a hard mask pattern formed of an oxide film.

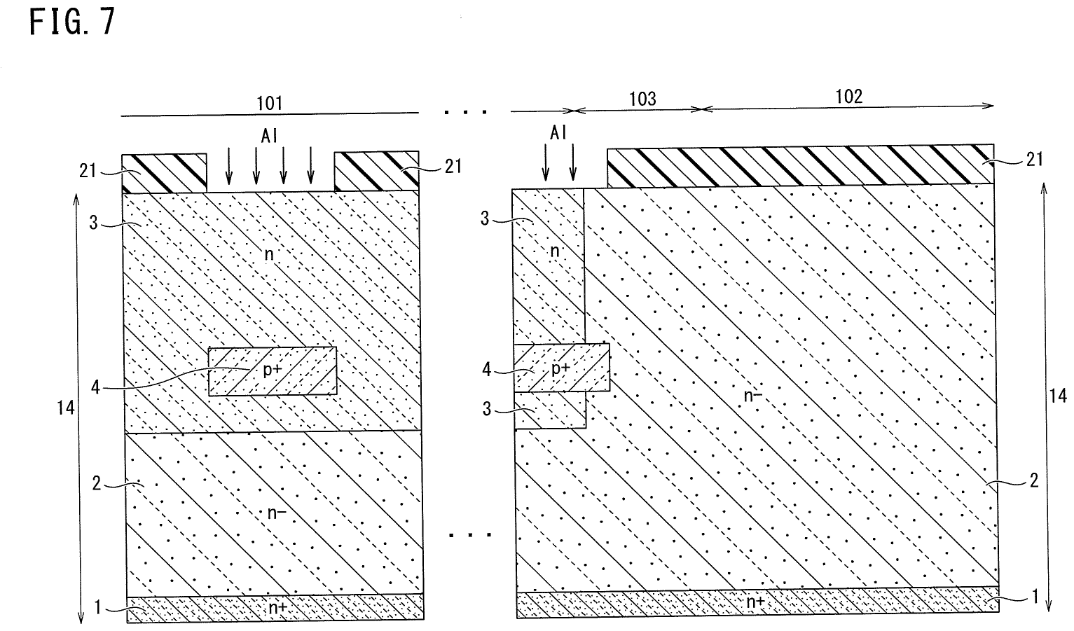

Next, as illustrated in FIG. 7, a mask pattern 21 of a photoresist film is formed on the top face of the drift layer 2. With the mask pattern 21 as an ion implantation mask, p type impurities such as aluminum (Al) are selectively ion implanted to selectively form a gate bottom protection region 4. The ion implantation of aluminum in the case is performed at a high acceleration energy of, for example, 780 keV or more and 960 keV or less for implantation to a deep region. The mask pattern 21 is then removed.

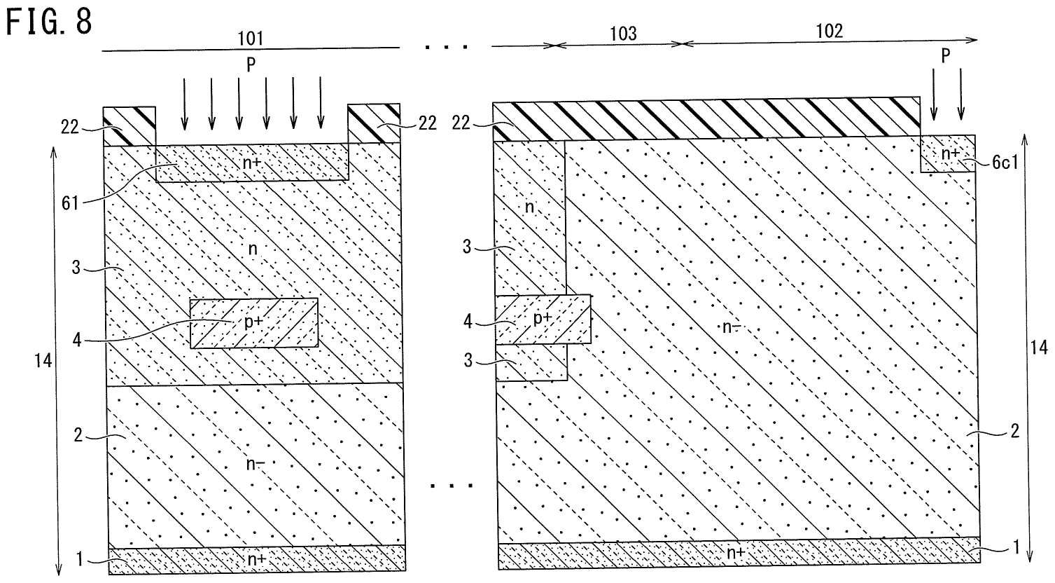

Next, as illustrated in FIG. 8, a mask pattern 22 of a photoresist film is formed on the top face of the drift layer 2. With the mask pattern 22 as an ion implantation mask, n type impurities such as phosphorus (P) and nitrogen (N) are selectively ion implanted. The dose amount at the ion implantation is set, for example, at less than about 2×10¹⁵ cm⁻². As a result, in the first silicon carbide layer 14, an n⁺ type source extension region 61 is selectively formed on the top face side of the drift layer 2 in the active part 101, and an n⁺ type first portion 6c1 is formed on the top face side of the drift layer 2 in the breakdown voltage structure part 102. The mask pattern 22 is then removed. The mask pattern 22 may be, for example, a hard mask pattern formed of an oxide film.

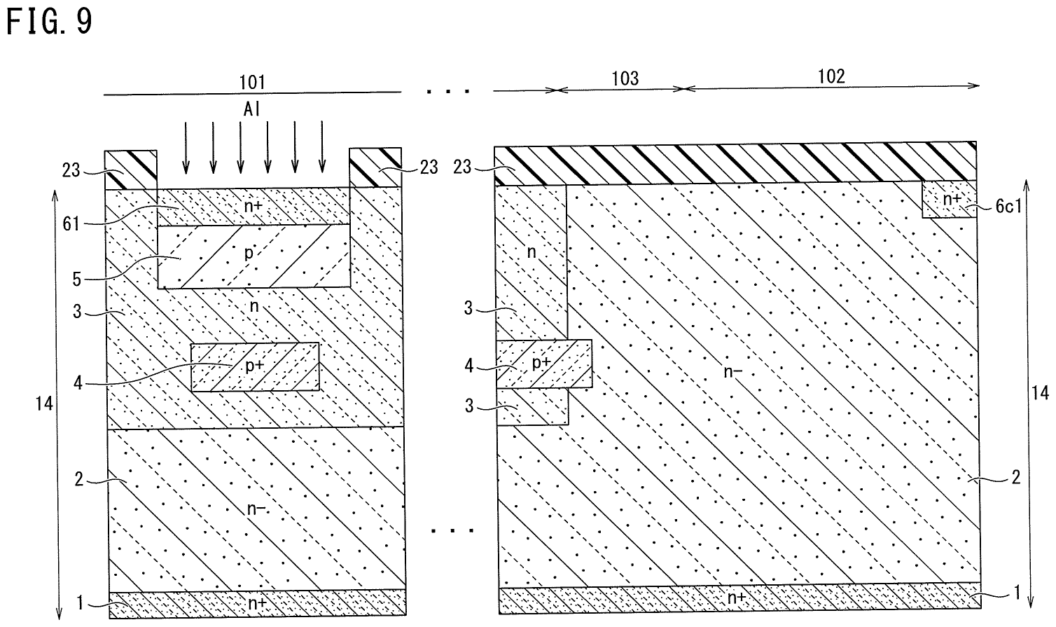

Next, as illustrated in FIG. 9, a mask pattern 23 of a photoresist film is formed on the top face of the drift layer 2. With the mask pattern 23 as an ion implantation mask, p type impurities such as aluminum (Al) are selectively ion implanted. As a result, in the current spreading layer 3, a base region 5 is selectively formed on the top face side of the current spreading layer 3 and on the bottom face side of the source extension region 61 in the active part 101, as illustrated in FIG. 9. The base region 5 is a region having the lowest impurity concentration in the regions formed of p type impurities. The mask pattern 23 is then removed. The mask pattern 23 may be, for example, a hard mask pattern formed of an oxide film.

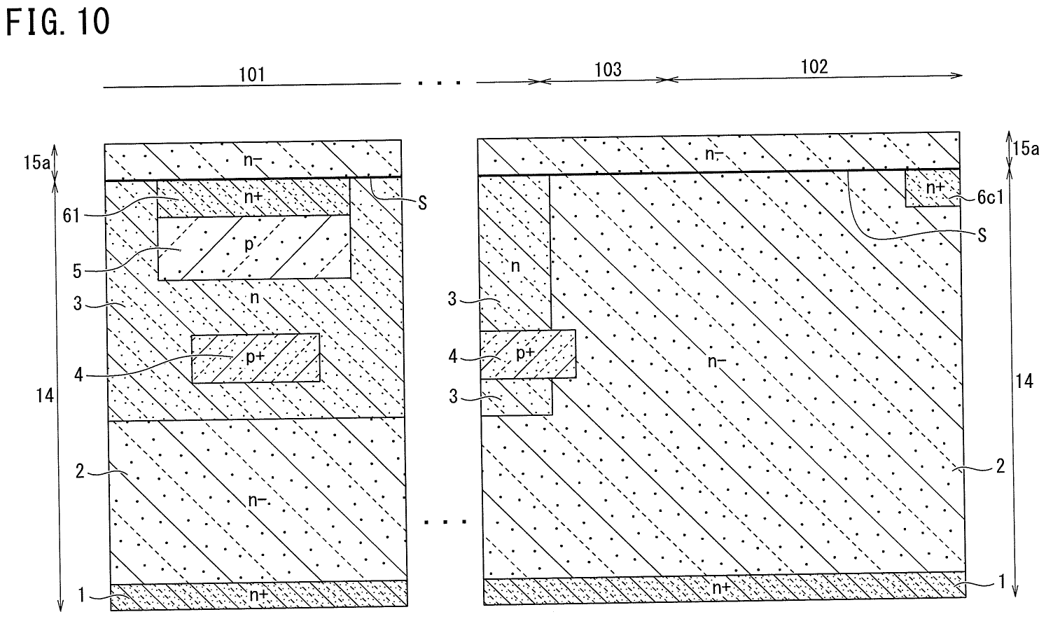

Next, as illustrated in FIG. 10, an amorphous film 15a of SiC is formed on the top face of the first silicon carbide layer 14 for forming a second silicon carbide layer 15. The amorphous film 15a is an n⁻ type SiC containing n type impurities such as N and has substantially the same n type impurity concentration as the drift layer 2. The amorphous film 15a is formed by a plasma enhanced CVD (plasma enhanced chemical vapor deposition method) or a sputtering method. The amorphous film 15a can be formed by the plasma enhanced chemical vapor deposition method at a temperature of, for example, about 300° C. or more and 650° C. or less. The amorphous film 15a can be formed by the sputtering method at a lower temperature than the case of the plasma enhanced chemical vapor deposition method and can be formed, for example, at room temperature.

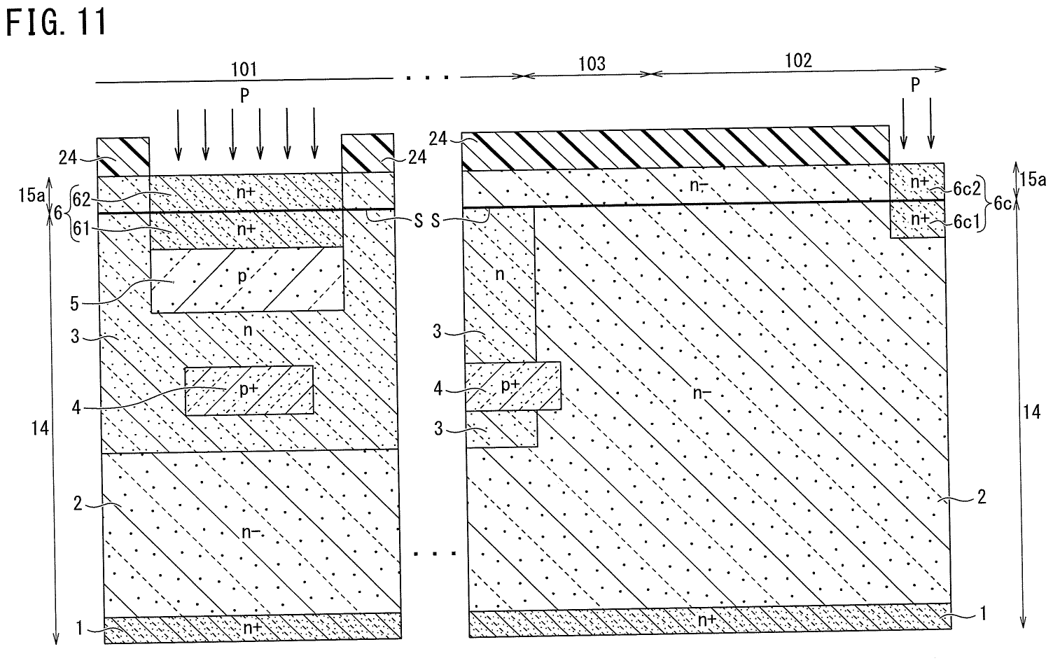

Next, as illustrated in FIG. 11, a mask pattern 24 of a photoresist film is formed on the top face of the amorphous film 15a. The mask pattern 24 has openings in positions overlapping with the source extension region 61 and the first portion 6c1. With the mask pattern 24 as an ion implantation mask, n type impurities such as phosphorus (P) and nitrogen (N) are selectively ion implanted. The dose amount at the ion implantation is, for example, set at substantially the same as the dose amount when the source extension region 61 and the first portion 6c1 are formed. As a result, in the amorphous film 15a on the top face of the source extension region 61, an n⁺ type source contact region 62 is selectively formed, and an n⁺ type second portion 6c2 is formed on the top face of the first portion 6c1. The source extension region 61 and the source contact region 62 constitute a source region 6, and the first portion 6c1 and the second portion 6c2 constitute a channel stopper region 6c. The mask pattern 24 is then removed. The mask pattern 24 may be, for example, a hard mask pattern formed of an oxide film.

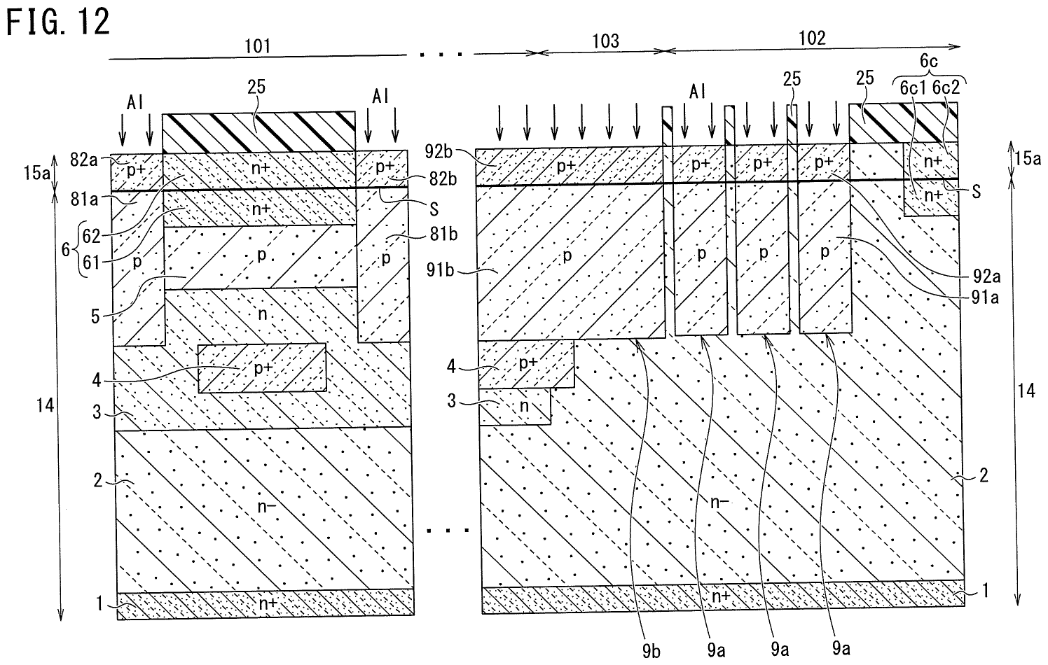

Next, as illustrated in FIG. 12, buried regions 81a, 81b, base contact regions 82a, 82b, field relaxation regions 9a, and a ring region 9b are formed. More specifically, ion implantation in a step of forming buried regions 81a, 81b and base contact regions 82a, 82b and ion implantation in a step of forming field relaxation regions 9a and a ring region 9b are simultaneously performed. First, a mask pattern 25 of a photoresist film is formed on the top face of the amorphous film 15a by a photolithographic technology. The mask pattern 25 may be, for example, a hard mask pattern formed of an oxide film. The mask pattern 25 has, in the active part 101, openings where base contact regions 82a, 82b are to be formed, has, in the breakdown voltage structure part 102, openings where field relaxation regions 9a are to be formed, and has, in the region 103, an opening where a ring region 9b is to be formed.

With the mask pattern 25 as an ion implantation mask, p type impurities such as aluminum (Al) are selectively ion implanted. By ion implantation in multiple stages, a higher impurity concentration of the top face side of SiC is achieved than in the deeper portion. For example, in a region close to the top face of Sic, the dose amount is set, for example, at about less than 2×10¹⁵ cm⁻². In a deep region apart from the top face of SiC, the dose amount may be set at a smaller value than the above. As a result, in the first silicon carbide layer 14, buried regions 81a, 81b are formed to be in contact with the base region 5 on the top face side of the current spreading layer 3 in the active part 101. In the amorphous film 15a on the top face of the buried regions 81a, 81b, base contact regions 82a, 82b are formed to be in contact with the source region 6.

In the breakdown voltage structure part 102, field relaxation regions 9a are formed. More specifically, in the first silicon carbide layer 14, first portions 91a of field relaxation regions 9a are formed on the top face side of the drift layer 2, and in the amorphous film 15a on the top face of the first portions 91a, second portions 92a are formed. In the region 103, a ring region 9b is formed. More specifically, in the first silicon carbide layer 14, a first portion 91b of a ring region 9b is formed on the top face side of the drift layer 2, and in the amorphous film 15a on the top face of the first portion 91b, a second portion 92b is formed. The mask pattern 25 is then removed.

Next, an activation annealing (heat treatment) step is performed. In the activation annealing step, activation annealing, for example, at about 1,400° C. or more and 1,900° C. or less simultaneously activates the p type impurities or the n type impurities that have been ion implanted in the gate bottom protection region 4, the base region 5, the source region 6, the buried regions 81a, 81b, the base contact regions 82a, 82b, the field relaxation regions 9a, the ring region 9b, and the like. The amorphous film 15a is recrystallized by heat treatment at a temperature of, for example 1,200° C. or more, and at least a part of the film is converted into 3C—SiC. By the above activation annealing, the amorphous film 15a can be recrystallized into a second silicon carbide layer 15. In other words, the heat treatment for recrystallizing the amorphous film 15a is not separately needed. Accordingly, at least a part of each of the source contact region 62, the base contact regions 82a, 82b, and the second portions 92a, 92b, 6c2 formed in the second silicon carbide layer 15 is converted into 3C—SiC. The source extension regions 61, the buried regions 81a, 81b, and the first portions 91a, 91b, 6c1 formed in the first silicon carbide layer 14 are still 4H—SiC even after activation annealing.

This embodiment exemplifies a case in which activation annealing is performed once after all the ion implantation steps are completed, but activation annealing may be performed multiple times after each ion implantation step. The ion implantation steps may be interchanged in some cases. A cap film of carbon (C) may be formed before activation annealing, activation annealing may be performed with the cap film, and the cap film may be removed after the activation annealing.

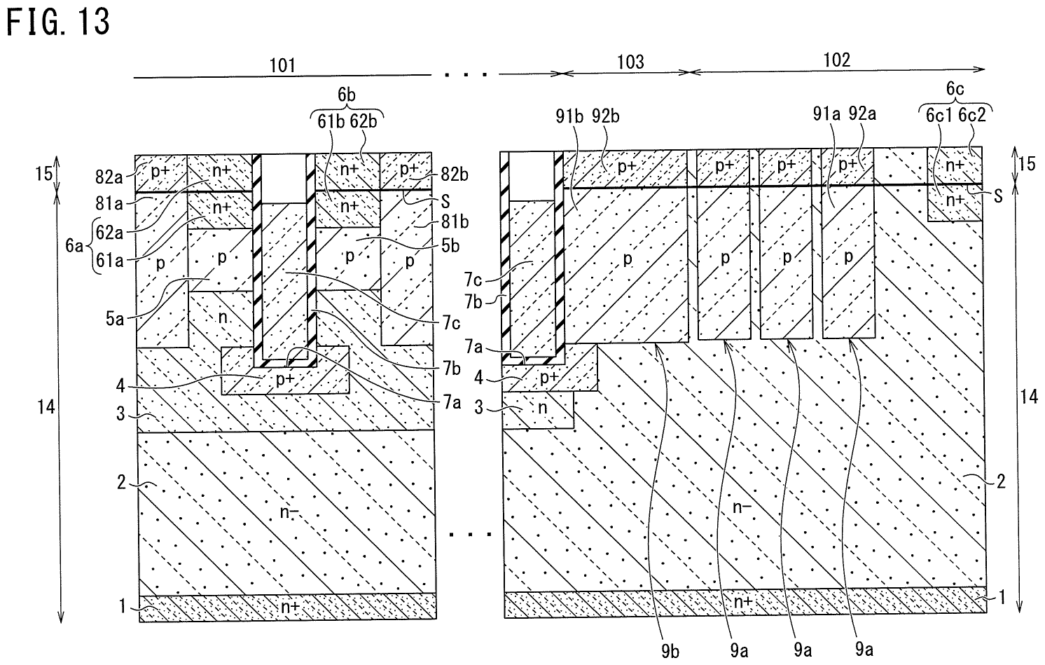

Next, as illustrated in FIG. 13, a trench forming step is performed. In the trench forming step, a hard mask pattern of an oxide film or the like is formed on the top face of the SiC by a photolithographic technology, a dry etching technology, a CVD technology, or the like. The hard mask pattern has an opening where a trench is to be formed. The hard mask pattern is then used as an etching mask to selectively form a trench 7a from the top face of the source region 6 in the depth direction by a dry etching technology such as reactive ion etching (RIE). In place of the hard mask pattern, a photoresist film may be used as the etching mask. The trench 7a penetrates the source region 6 and the base region 5, further digs the upper part of the current spreading layer 3, and reaches the gate bottom protection region 4. The source region 6 is divided into source regions 6a, 6b, and the base region 5 is divided into base regions 5a, 5b. The etching mask is then removed.

Next, a gate insulating film/gate electrode forming step is performed. In the gate insulating film/gate electrode forming step, a gate insulating film 7b is formed on the bottom face and side faces of the trench 7a by a CVD technology, a high temperature oxidation (HTO) method, a thermal oxidation method, or the like. Next, a polysilicon layer (doped polysilicon layer) containing impurities such as phosphorus (P) and boron (B) at a high concentration is deposited by a CVD technology or the like such that the inside of the trench 7a is embedded. Then, a part of the polysilicon layer and a part of the gate insulating film 7b are selectively removed by a photolithographic technology and dry etching. As a result, an insulated gate electrode structure (7b, 7c) including the gate insulating film 7b and the gate electrode 7c is formed as illustrated in FIG. 13. More specifically, the polysilicon layer is etched back such that the top face of the gate electrode 7c in contact with the gate insulating film 7b is deeper than the boundary face S between the second silicon carbide layer 15 and the first silicon carbide layer 14.

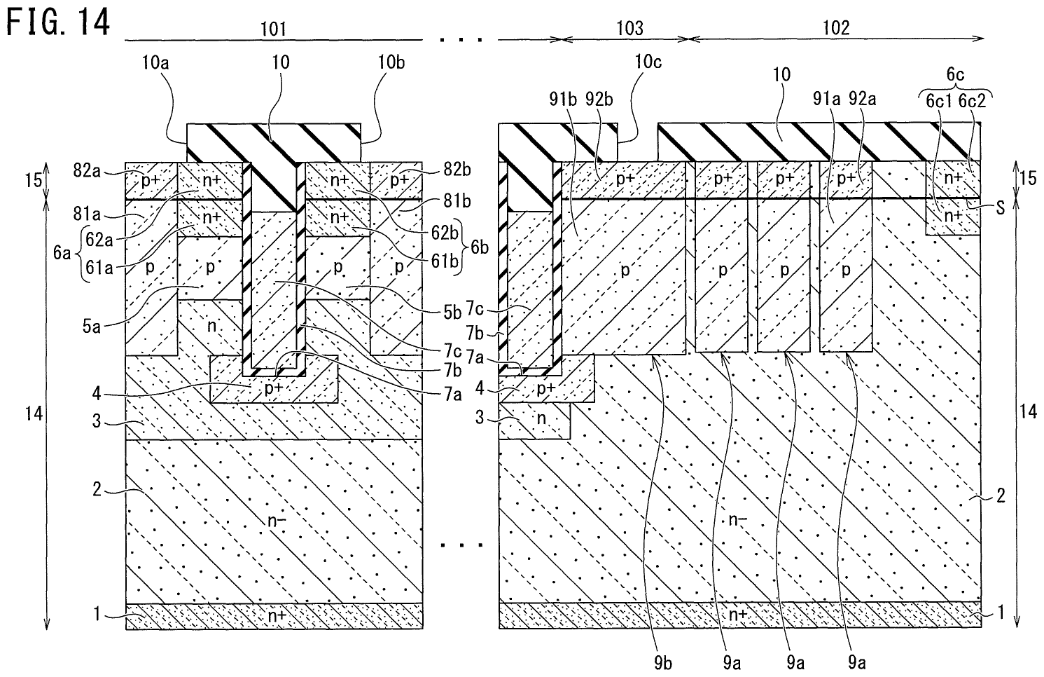

Next, as illustrated in FIG. 14, an insulating film 10 is deposited on the top face of the SiC by a CVD technology or the like. A part of the insulating film 10 is selectively removed by a photolithographic technology, a dry etching technology, or the like to make, in the insulating film 10, contact holes 10a, 10b through which the top faces of the source regions 6a, 6b and the base contact regions 82a, 82b are exposed. In addition, a contact hole 10c through which the top face of the ring region 9b is exposed is made. Heat treatment (reflow) may then be performed for planarization of the insulating film 10.

Next, a barrier metal layer 11 and a source wiring electrode 12 are sequentially formed by a sputtering technology, an evaporation method, or the like so as to cover the top face and side faces of the insulating film 10 and the top faces of the source regions 6a, 6b, the base contact regions 82a, 82b, and the ring region 9b, and a source electrode (11, 12) illustrated in FIG. 2 is formed. The barrier metal layer 11 is in contact with the source regions 6a, 6b, the base contact regions 82a, 82b, and the ring region 9b. The barrier metal layer 11 is in ohmic contact with the source regions 6a, 6b, the base contact regions 82a, 82b, and the ring region 9b at a low resistance.

Next, the SiC substrate 1 is subjected to grinding, chemical mechanical polishing (CMP), or the like to decrease the thickness from the bottom face side and to adjust the thickness, and a drain region 1 is formed. Next, a drain electrode 13 is formed from gold (Au) or the like on the entire bottom face of the drain region 1 by a sputtering method, an evaporation method, or the like (see FIG. 2). Through the above process, a SiC semiconductor device illustrated in FIG. 2 is completed.

In a conventional case, a hexagonal single crystal silicon carbide substrate is subjected to ion implantation of phosphorus to form an amorphous layer, and the amorphous layer is recrystallized by heat treatment into cubic single crystals of n type silicon carbide. However, ion implantation of impurities may give an unclear boundary between a high impurity concentration region and a low impurity concentration region in the SiC. Accordingly, the SiC after heat treatment may have an unclear boundary between a region containing 3C—SiC and a region of 4H—SiC. In particular, in a trench type SiC semiconductor device, a region containing 3C—SiC for suppressing the contact resistance is required to be prepared separately from a region of 4H—SiC along the depth direction. If 3C—SiC is formed by ion implantation of impurities, the boundary between a region containing 3C—SiC and a region containing almost no 3C—SiC may become unclear. Accordingly, in a trench type SiC semiconductor device, the boundary between a region containing 3C—SiC and a region containing almost no 3C—SiC may not be easily specified. In some cases, a little more margin may be designed to suppress leak current i, and a little more amount of fall do of a gate electrode 7c from the top face of a source contact region 62a may be set. As described above, the device design flexibility may decrease.

In contrast, the method for manufacturing a SiC semiconductor device 100 pertaining to the first embodiment includes a step of forming (preparing) a first silicon carbide layer 14 containing silicon carbide with a 4H structure and including a first conductivity type drift layer 2 and a step of stacking a second silicon carbide layer 15 containing silicon carbide with a 3C structure on the top face of the first silicon carbide layer 14. In other words, in the technology, the second silicon carbide layer 15 is formed by a film deposition method, and thus the boundary between the region containing 3C—SiC and the region mainly formed of silicon carbide with a 4H structure becomes clear as the boundary face S. It is thus obvious that a region deeper than the boundary face S contains no mixed crystals of 3C—SiC and 4H—SiC or contains few mixed crystals of 3C—SiC and 4H—SiC if any, and thus the top face 7d of the gate electrode 7c in contact with the gate insulating film 7b can be designed at a position deeper than the boundary face S. Accordingly, leak current i can be suppressed without setting a little more margin, and the decrease in the device design flexibility can be suppressed.

In a case of forming 3C—SiC by subjecting 4H—SiC to ion implantation of impurities to give an amorphous layer and by heat-treating the amorphous layer (hereinafter called a case of forming 3C—SiC by ion implantation), an expensive system is needed. More specifically, to convert 4H—SiC into an amorphous layer, ion implantation of impurities at a high concentration is needed, and an expensive ion implantation system is required to be operated for a longer time.

In contrast, in the method for manufacturing a SiC semiconductor device 100 pertaining to the first embodiment, an amorphous film 15a is directly formed on the top face of the first silicon carbide layer 14 by a plasma enhanced chemical vapor deposition method or a sputtering method, and thus can be formed with a less expensive system than the ion implantation system.

To form 3C—SiC by ion implantation, a portion of 4H—SiC that is subsequently converted into 3C is required to be formed in advance. Forming 4H—SiC requires epitaxial growth with a thermal CVD (thermal chemical vapor deposition) system at a high temperature of, for example, about 1,600° C.

In contrast, in the method for manufacturing a SiC semiconductor device 100 pertaining to the first embodiment, an amorphous film 15a can be formed at a lower temperature than when 3C—SiC is formed by ion implantation. More specifically, the amorphous film 15a can be formed by a plasma enhanced chemical vapor deposition method at a temperature of, for example, about 300° C. or more and 650° C. or less. The amorphous film 15a can also be formed by a sputtering method at a lower temperature than by the plasma enhanced chemical vapor deposition method and can be formed, for example, at room temperature. As described above, in the method for manufacturing a SiC semiconductor device 100 pertaining to the first embodiment, the processing can be performed at a lower temperature than when 3C—SiC is formed by ion implantation, and this can suppress the manufacturing cost. The amorphous film 15a is recrystallized by heat treatment at a temperature of, for example, 1,200° C. or more, and thus can be recrystallized simultaneously with the activation of p type impurities or n type impurities that have been ion implanted into SiC. The heat treatment for recrystallizing the amorphous film 15a is not separately needed, and this can suppress the manufacturing cost.

### Alternative Example 1 of First Embodiment

In the method for manufacturing a SiC semiconductor device pertaining to the first embodiment, in order to form a second silicon carbide layer 15, an amorphous film 15a of SiC is formed on the top face of the first silicon carbide layer 14, and then the amorphous film 15a is recrystallized by heat treatment, as illustrated in FIG. 10, but the present technology is not limited to the process. In a method for manufacturing a SiC semiconductor device pertaining to alternative example 1 of the first embodiment, a second silicon carbide layer 15 containing 3C—SiC may be directly formed in place of the amorphous film 15a on the top face of the first silicon carbide layer 14 in FIG. 10. In this case, the second silicon carbide layer 15 is formed by a thermal CVD method (thermal chemical vapor deposition method).

Even by the method for manufacturing a SiC semiconductor device pertaining to the alternative example 1 of the first embodiment, substantially the same effect as in the first embodiment can be achieved. More specifically, the second silicon carbide layer 15 containing 3C—SiC can be formed with a less expensive system than the ion implantation system. When the second silicon carbide layer 15 is formed by the thermal CVD method, the treatment temperature is, for example, about 800° C. or more and 1,100° C. or less, which is higher than the temperature for forming the amorphous film 15a but is lower than the treatment temperature when 3C—SiC is formed by ion implantation. This can reduce the manufacturing cost as compared with when 3C—SiC is formed by ion implantation. The manufacturing method other than the above is the same as the manufacturing method described in the first embodiment and thus will not be described. In the method for manufacturing a SiC semiconductor device pertaining to the alternative example 1 of the first embodiment, a second silicon carbide layer 15 containing 3C—SiC is directly formed, and thus heat treatment for 3C is not needed.

### Other Embodiments

The first embodiment of the present disclosure has been described as above, but the description and drawings constituting a part of the disclosure should not be understood to limit the disclosure. From the disclosure, various alternative embodiments, examples, and operational technologies will be apparent to a person skilled in the art.

For example, as the semiconductor device pertaining to the first embodiment, a MOSFET is exemplified, but the present disclosure is also applicable to an insulated gate bipolar transistor (IGBT) having a structure in which a p⁺ type collector region is provided in place of the n⁺ type drain region 1. In addition to the IGBT alone, the present disclosure is further applicable to a reverse conduction IGBT (RC-IGBT) or a reverse blocking insulated gate bipolar transistor (RB-IGBT).

In the first embodiment, the field relaxation region 9a has been described as a guard ring but may have a JTE structure.

The configurations disclosed in the first embodiment may be appropriately combined to the extent that no inconsistency arises. Needless to say, the disclosure includes various embodiments and the like not described in the above description. The technical scope of the present disclosure is therefore defined only by the invention specifying matters pertaining to the claims and reasonable from the above description.

What is claimed is:

1. A silicon carbide semiconductor device comprising:
a first silicon carbide layer containing silicon carbide with a 4H structure;
a second silicon carbide layer containing silicon carbide with a 3C structure and stacked on a top face of the first silicon carbide layer;
a first conductivity type drift layer provided in the first silicon carbide layer;
a second conductivity type base region provided in the first silicon carbide layer on a top face side of the drift layer;
a first conductivity type main region including a source extension region provided in the first silicon carbide layer and having a bottom face in contact with the base region and a source contact region provided in the second silicon carbide layer and having a bottom face in contact with the source extension region;
a gate insulating film provided in a trench penetrating the main region and the base region;
a gate electrode embedded on the gate insulating film in the trench; and
a main electrode provided in contact with the source contact region.

2. The silicon carbide semiconductor device according to claim 1, wherein a top face of the gate electrode in contact with the gate insulating film is deeper than a boundary face between the second silicon carbide layer and the first silicon carbide layer.

3. The silicon carbide semiconductor device according to claim 1, wherein the source extension region and the source contact region are divided by the boundary face between the first silicon carbide layer and the second silicon carbide layer.

4. The silicon carbide semiconductor device according to claim 1, wherein the top face of the gate electrode in contact with the gate insulating film is shallower than a bottom face of the source extension region.

5. The silicon carbide semiconductor device according to claim 1, wherein the second silicon carbide layer has a thickness of 0.2 μm or more and 0.5 μm or less.

6. The silicon carbide semiconductor device according to claim 1, wherein the second silicon carbide layer contains silicon carbide with a 3C structure at a proportion of 10 percent or more and 100 percent or less.

7. The silicon carbide semiconductor device according to claim 1, further comprising a second conductivity type base contact region provided in the second silicon carbide layer, wherein
the base contact region has a side face in contact with the main region, has a top face in contact with the main electrode, and has a dimension along a depth direction equal to that of the source contact region.

8. The silicon carbide semiconductor device according to claim 1, wherein the silicon carbide semiconductor device includes an active part and a breakdown voltage structure part surrounding a periphery of the active part in plan view,
the second silicon carbide layer is stacked on the top face of the first silicon carbide layer over the active part and the breakdown voltage structure part, and
the base region, the main region, and the trench are provided in the active part.

9. The silicon carbide semiconductor device according to claim 8, further comprising a field relaxation region formed of a second conductivity type silicon carbide and provided in the breakdown voltage structure part over the second silicon carbide layer and the first silicon carbide layer in the depth direction.

10. A method for manufacturing a silicon carbide semiconductor device, the method comprising:
forming a first silicon carbide layer containing silicon carbide with a 4H structure and including a first conductivity type drift layer;
stacking a second silicon carbide layer containing silicon carbide with a 3C structure on a top face of the first silicon carbide layer;
forming a second conductivity type base region in the first silicon carbide layer on a top face side of the drift layer;
forming a first conductivity type main region having a multilayer structure of a source extension region and a source contact region over the first silicon carbide layer and the second silicon carbide layer;
forming a trench penetrating the main region and the base region located on a bottom face side of the main region;
forming a gate electrode on a gate insulating film in the trench; and
forming a main electrode to be in contact with a top face of the source contact region, wherein
in the forming a main region, the source extension region is formed in the first silicon carbide layer, and the source contact region is formed in the second silicon carbide layer.

11. The method for manufacturing a silicon carbide semiconductor device according to claim 10, wherein in the forming a gate electrode, a top face of the gate electrode in contact with the gate insulating film is provided to be deeper than a boundary face between the second silicon carbide layer and the first silicon carbide layer.

12. The method for manufacturing a silicon carbide semiconductor device according to claim 10, wherein the stacking a second silicon carbide layer includes forming an amorphous film of silicon carbide on the top face of the first silicon carbide layer and heat-treating the amorphous film.

13. The method for manufacturing a silicon carbide semiconductor device according to claim 12, wherein the amorphous film is formed by a plasma enhanced chemical vapor deposition method or a sputtering method.

14. The method for manufacturing a silicon carbide semiconductor device according to claim 10, wherein the stacking a second silicon carbide layer includes forming a silicon carbide film containing silicon carbide with a 3C structure on the top face of the first silicon carbide layer.

15. The method for manufacturing a silicon carbide semiconductor device according to claim 14, wherein the second silicon carbide layer is formed by a thermal chemical vapor deposition method.

16. The method for manufacturing a silicon carbide semiconductor device according to claim 10, wherein the source contact region is formed by subjecting the second silicon carbide layer to ion implantation of an n type impurity.

17. The method for manufacturing a silicon carbide semiconductor device according to claim 10, further comprising subjecting the second silicon carbide layer to ion implantation of a p type impurity to form a base contact region in contact with the source contact region.
